(19) United States
(12) Patent Application Publication
(10) Pub. No.: US 2011/0088756 A1
(43) Pub. Date: Apr. 21, 2011

(54) Adhesive seal material for end portion of solar cell panel, sealed structure of end portion of solar cell panel, sealing method, solar cell module, and producing method thereof

(75) Inventors: Hiroki Fujii, Osaka (JP); Masahiko Kosuga, Osaka (JP); Masayuki Ishikawa, Osaka (JP)

(73) Assignee: Nitto Denko Corporation, Osaka (JP)

(21) Appl. No.: 12/923,781

(22) Filed: Oct. 7, 2010

(30) Foreign Application Priority Data
Oct. 17, 2009 (JP) 2009-239913

(51) Int. Cl. H01L 31/048; H01L 31/18; B32B 7/12; C09J 7/02

(52) U.S. Cl. 136/251; 29/890.033; 428/356; 428/317.3

(57) ABSTRACT

An adhesive seal material for an end portion a solar cell panel is an adhesive seal material which is bonded to an end portion of a solar cell panel. The adhesive seal material includes a rubber-based adhesive layer, and a non-adhesive layer partially covering a surface of the rubber-based adhesive layer.

### CROSS-REFERENCE TO RELATED APPLICATION

The present application claims priority from Japanese Patent Application No. 2009-239913 filed on Oct. 17, 2009, the content of which is hereby incorporated by reference into this application.

### BACKGROUND OF THE INVENTION

1. Field of the Invention

The present invention relates to an adhesive seal material for an end portion of a solar cell panel, a sealed structure of an end portion of a solar cell panel, a sealing method, a solar cell module, and a producing method thereof. More particularly, the present invention relates to an adhesive seal material for an end portion of a solar cell panel which is bonded to an end portion of a solar cell panel, a sealed structure of the end portion of the solar cell panel using the same, a sealing method, a solar cell module, and a producing method thereof.

2. Description of the Related Art

A solar cell module is produced by incorporating a solar cell panel (crystalline-silicon solar cell panel), which is formed by sealing a silicon cell formed on a glass substrate with an ethylene-vinyl acetate (EVA) resin or the like and further providing a back sheet, into a frame. Since a solar cell module is used outdoors, avoidance of water penetration into the panel is required.

To prevent water penetration into a panel, a seal material made of, e.g., a hot-melt resin or the like is poured into a frame material to fill the inside thereof, and then a peripheral end portion of the solar cell panel is inserted into the frame material (see Japanese Unexamined Patent Nos. 2005-277260 and 2009-099805). Also, a tape-type seal material is examined which is bonded in advance to a module (see Japanese Unexamined Patent No. 2009-071233).

It is also practiced to place a foam seal material in a compressed state between a panel and a frame. In particular, as an advantageous method for automated bonding without protrusion of a seal material, it is known to bond a foam seal material to an end portion of a panel to cover the upper, lower, and end surfaces of a near-end portion of the panel, and then incorporate the panel into a frame (fit the panel into the framework of the frame) (see Japanese Unexamined Patent Nos. 2003-137611 and 2009-071233).

### SUMMARY OF THE INVENTION

However, in a method according to each of Japanese Unexamined Patent Nos. 2005-277260 and 2009-099805, to reduce the stress received by the solar cell panel upon insertion of the solar cell panel into the frame material, it is necessary to heat and melt the seal material in advance. This results in the problem of lower productivity. In addition, with the method described above, it is difficult to set an amount of the seal material to be packed. That is, if the amount of the packed seal material is excessively small, a problem arises that a water vapor barrier property deteriorates to degrade reliability. On the other hand, if the amount of the packed seal material is excessively large, a problem arises that the seal material protrudes out of the frame material to reduce a production yield.

In a method according to Japanese Unexamined Patent No. 2009-071233, when the panel is fitted into the frame, an excessively high adhesive force may result in resistance to make it difficult to fit the panel into the frame, and reduce workability. Accordingly, to temporarily reduce the adhesive force, the step of applying a surface tension modifier, such as soap water, to the surface of the frame-side adhesive material may be performed. This not only reduces workability, but also causes concern about degraded reliability due to moisture remaining in the frame during a module production process.

In a method according to each of Japanese Unexamined Patent Nos. 2003-137611 and 2009-071233, an elastic layer is compressed when the solar cell panel is press-fitted into the frame so that it is difficult to set the compressibility thereof. That is, if the compressibility is excessively high, an excess stress is placed on the solar cell panel to result in the problem that distortion (deformation) occurs in the solar cell panel. On the other hand, if the compressibility is excessively low, a problem arises that the water vapor barrier property deteriorates, and the solar cell panel eventually slips out of the frame.

Additionally, the two methods described above have the problem that, after the peripheral end portion of the solar cell panel is inserted into the frame, temporarily removed to the outside of the frame, and then aligned, it is difficult to insert the peripheral end portion of the solar cell panel again into the frame (rework).

An object of the present invention is to provide an adhesive seal material for an end portion of a solar cell panel which is bonded to an end portion of a solar cell panel to allow the end portion thereof to be disposed in a fixing member with high workability and high reworkability, and then securely fixes the end portion of the solar cell panel to allow the end portion thereof to reliably have an excellent water vapor barrier property, a sealed structure of the end portion of the solar cell panel, a sealing method, a solar cell module, and a producing method thereof.

As a result of making an intensive study to solve the problems described above, the present inventors have found that, by using a rubber-based adhesive layer as an adhesive layer forming an adhesive seal material for an end portion of a solar cell panel, and providing a surface thereof with a non-adhesive layer partially covering the surface, it is possible to obtain excellent lubricity in a direction along the surface of the adhesive seal material for the end portion of a solar cell panel, and obtain adhesiveness in a thickness direction, and completed the present invention.

That is, an aspect of the present invention is an adhesive seal material for an end portion of a solar cell panel which is bonded to an end portion of a solar cell panel, including a rubber-based adhesive layer, and a non-adhesive layer partially covering a surface of the rubber-based adhesive layer. It is particularly preferable that a porous screen is provided as the non-adhesive layer.

In the adhesive seal material for the end portion of the solar cell panel of the present invention, it is preferable that the rubber-based adhesive layer is formed from a butyl-rubber-based adhesive composition.

In the adhesive seal material for the end portion of the solar cell panel of the present invention, it is preferable that a coverage ratio of the non-adhesive layer is in a range of 5 to 50%.

In the adhesive seal material for the end portion of the solar cell panel of the present invention, the adhesive seal material is trimmed into a size of 2 cm×2 cm to produce a sample, the surface of the rubber-based adhesive layer of the sample where the non-adhesive layer is formed is brought into contact with an aluminum plate while a load of 30 g is placed on the sample, the sample is pulled in a direction along the aluminum plate at a speed of 300 mm/minute, and a frictional force defined as a stress during the pulling is in a range of 0.01 to 1.0 N/4 cm².

A solar cell module of the present invention includes a solar cell panel, an adhesive seal material for an end portion of the solar cell panel which includes a rubber-based adhesive layer and a non-adhesive layer partially covering a surface of the rubber-based adhesive layer, and seals the end portion of the solar cell panel, and a fixing member for fixing the end portion of the solar cell panel via the adhesive seal material.

In a sealed structure of an end portion of a solar cell panel of the present invention, an adhesive seal material for the end portion of the solar cell panel which includes a rubber-based adhesive layer and a non-adhesive layer partially covering a surface of the rubber-based adhesive layer is bonded to the end portion of the solar cell panel, and then the adhesive seal material and the end portion of the solar cell panel are disposed in a fixing member such that the end portion of the solar cell panel is fixed with the fixing member via the adhesive seal material. It is particularly preferable that the adhesive seal material is bonded to the end portion of the solar cell panel such that the surface of the rubber-based adhesive layer where the non-adhesive layer is formed comes in contact with the fixing member.

A sealing method of an end portion of a solar cell panel of the present invention includes bonding an adhesive seal material for the end portion of the solar cell panel which includes a rubber-based adhesive layer and a non-adhesive layer partially covering a surface of the rubber-based adhesive layer to the end portion of the solar cell panel, and disposing the adhesive seal material and the end portion of the solar cell panel in a fixing member to fix the end portion of the solar cell panel with the fixing member via the adhesive seal material. It is particularly preferable that the adhesive seal material is bonded to the end portion of the solar cell panel such that the surface of the rubber-based adhesive layer where the non-adhesive layer is formed comes in contact with the fixing member.

A producing method of a solar cell module of the present invention includes bonding an adhesive seal material for an end portion of a solar cell panel which includes a rubber-based adhesive layer and a non-adhesive layer partially covering a surface of the rubber-based adhesive layer to an end portion of a solar cell panel, and then disposing the adhesive seal material and the end portion of the solar cell panel in a fixing member to fix the end portion of the solar cell panel with the fixing member via the adhesive seal material. It is particularly preferable that the adhesive seal material is bonded to the end portion of the solar cell panel such that the surface of the adhesive layer where the non-adhesive layer is formed comes in contact with the fixing member.

The adhesive seal material for an end portion of a solar cell panel of the present invention easily adheres to the end portion of the solar cell panel to allow the end portion thereof to be disposed in the fixing member with high workability.

By subsequently applying pressure, the adhesive force of the adhesive seal material is increased, and therefore it is possible to securely fix the end portion of the solar cell panel to the fixing member via the adhesive seal material, and reliably seal the end portion of the solar cell panel. This allows the end portion of the solar cell panel to have an excellent water vapor barrier property.

As a result, it is possible to obtain a solar cell module of the present invention which has excellent water resistance and reliability, while ensuring high workability and high production efficiency.

### BRIEF DESCRIPTION OF THE DRAWINGS

FIG. 1 is a view showing an embodiment of an adhesive seal material for an end portion of a solar cell panel of the present invention, which is a schematic top view of an adhesive seal material for an end portion of a solar cell panel in which a non-adhesive layer is formed on a surface of an adhesive layer;

FIG. 2 is a view showing the embodiment of the adhesive seal material for an end portion of a solar cell panel of the present invention, which is a schematic A-A cross-sectional view of the adhesive seal material of FIG. 1 in which the non-adhesive layer is formed on the surface of the adhesive layer;

FIG. 3 shows the adhesive layer on which the non-adhesive layer is formed, and an object in contact with the surface of the adhesive layer where the non-adhesive layer is provided,

(a) showing a schematic cross-sectional view thereof in a state without applied pressure, and

(b) showing a schematic cross-sectional view thereof in a state with applied pressure;

FIG. 4 is a partially cross-sectional perspective view showing an embodiment of a solar cell module of the present invention; and

FIG. 5 is a process step view illustrating an embodiment of a producing method of the solar cell module of the present invention,

(a) showing a step of bonding an adhesive seal material for an end portion of a solar cell panel to a peripheral end portion of a solar cell panel, and

(b) showing a step of disposing the peripheral end portion of the solar cell panel in a frame, and sealing the peripheral end portion thereof.

### DETAILED DESCRIPTION OF THE INVENTION

An adhesive seal material for an end portion of a solar cell panel of the present invention is an adhesive seal material which is bonded to an end portion of a solar cell panel, and includes a rubber-based adhesive layer, and a non-adhesive layer partially covering a surface of the rubber-based adhesive layer.

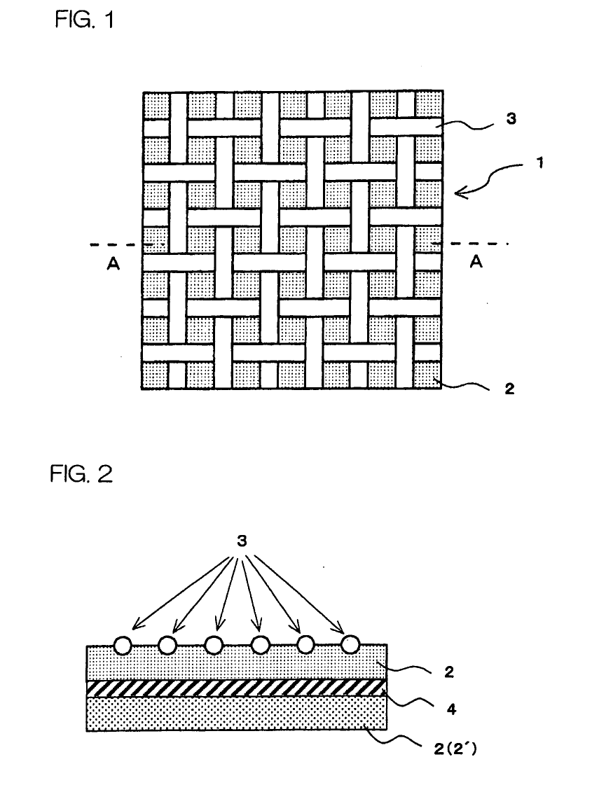

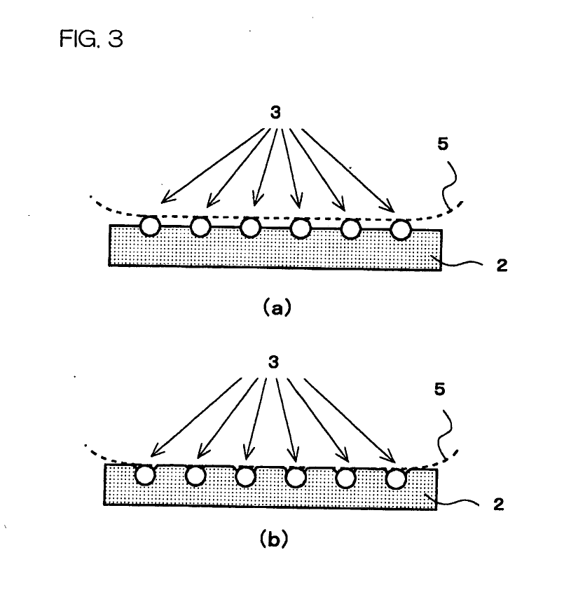

Referring to FIGS. 1 and 2, a description is given to the adhesive seal material for an end portion of a solar cell panel of the present invention.

FIG. 1 is a schematic top view of an adhesive seal material for an end portion of a solar cell panel in which a non-adhesive layer is formed on a surface of a rubber-based adhesive layer. FIG. 2 is a schematic A-A cross-sectional view of the adhesive seal material of FIG. 1. In FIGS. 1 and 2, 1 denotes the adhesive seal material for an end portion of a solar cell panel, 2 (2′) denotes the rubber-based adhesive layer, 3 denotes the non-adhesive layer, and 4 denotes a base material. Note that FIGS. 1 and 2 show the case where a porous screen is used as the non-adhesive layer 3, and show the porous screen having quadrilateral meshes, but the shape of the mesh is not limited to the quadrilateral. FIGS. 1 and 2 also show the adhesive seal material of a base-equipped type in which the adhesive layers are formed on the both surfaces of the base material 4, and the non-adhesive layer 3 is formed only on the surface of one of the adhesive layers. However, the adhesive seal material for an end portion of a solar cell panel may also be of a no-base type which does not have a base material (base material layer).

### (Rubber-Based Adhesive Layer)

Examples of the rubber-based adhesive layer 2 include a layer containing a rubber as a main component, specifically a layer made of a rubber-based adhesive composition in which a known additive is uniformly mixed and dispersed in a rubber, and the like. Examples of such a rubber include a synthetic rubber such as a butyl rubber, polyisobutylene, a crosslinked butyl rubber, rubberized asphalt, or EPDM, a natural rubber, and the like

Among these rubbers, it is preferable to use a butyl rubber as a main component in terms of a water vapor barrier property, endurance, and the like. The type of the butyl rubber is not particularly limited. Examples of the butyl rubber to be used include a reclaimed butyl rubber, a synthetic butyl rubber, and the like. Preferably, a reclaimed butyl rubber with excellent processability is used. As the butyl rubber, one type can be used alone or a plurality of types can be used in combination.

The Mooney viscosity of the butyl rubber is in a range of, e.g., 30 to 60 (ML1+4, 100° C.), or preferably 35 to 55 (ML1+4, 100° C.).

The rubber-based adhesive composition forming the rubber-based adhesive layer 2 contains a rubber as a main component, and also contains a tackifier, a filler, a softener, and the like as optional components.

The mixing ratio of the rubber component to 100 parts by weight of the rubber-based adhesive composition is in a range of, e.g., 10 to 50 parts by weight, or preferably 20 to 40 parts by weight.

Examples of the tackifier to be used include a rosin-based resin, a terpene-based resin, a coumarone-indene-based resin (coumarone-based resin), a petroleum-based resin (such as e.g., a cycloaliphatic petroleum resin, an aliphatic/aromatic copolymer petroleum resin, an aromatic petroleum resin, and e.g., a C5/C6 petroleum resin, a C5 petroleum resin, a C9 petroleum resin, or a C5/C9 petroleum resin), a phenol-based resin (such as, e.g., a terpene-denatured phenol resin), and the like. The softening point of the tackifier is in a range of, e.g., 50 to 150° C., or preferably 50 to 130° C.

Examples of the filler to be used include magnesium oxide, calcium carbonate (such as, e.g., heavy calcium carbonate, light calcium carbonate, or Hakuenka™ (coloidal calcium carbonate)), talc, mica, clay, mica powder, bentonite (such as, e.g., organic bentonite), silica, alumina, aluminum hydroxide, aluminum silicate, titanium oxide, carbon black (such as, e.g., insulating carbon block or acetylene black), aluminum powder, glass balloon, and the like. One filler may be used alone or two or more fillers may be used in combination. By using a hollow filler with a small specific gravity such as glass balloon, the rubber-based adhesive layer can be reduced in weight without using a foaming agent.

Examples of a softener to be used include polybutene (such as, e.g., liquid polybutene), process oil, and the like. Each of the optional components may be used alone or two or more thereof may be used in combination. The mixing ratio of the total amount of the optional components to 100 parts by weight of the rubber component is in a range of, e.g., 100 to 1000 parts by weight, or preferably 200 to 500 parts by weight.

The mixing ratio of each of the optional components to 100 parts by weight of the rubber component is such that the mixing ratio of the tackifier thereto is in a range of, e.g., 20 to 200 parts by weight, or preferably 30 to 150 parts by weight, the mixing ratio of the filler thereto is in a range of, e.g., 10 to 300 parts by weight, or preferably 50 to 200 parts by weight, and the mixing ratio of the softener thereto is in a range of 5 to 50 parts by weight, or preferably 10 to 40 parts by weight.

To the adhesive composition, a known additive added to the back-side adhesive composition such as a vulcanizer, an age resistor, a plasticizer, or a vulcanization accelerator can be added at an appropriate ratio.

To prepare the adhesive composition, the individual components shown above are mixed at the foregoing mixing ratios, and kneaded. The individual components are kneaded with, e.g., a mixing roll, a kneader (such as, e.g., a pressure kneader or an open kneader), an extruder, or the like. Preferably, the individual components are kneaded with a kneader.

In the case where the pressure kneader or open kneader is used as the kneader, a heating temperature in the kneading is in a range of, e.g., 100 to 120° C.

In the preparation of the adhesive composition, a simultaneous charging method or a master batch method (divided charging method), e.g., is used and, preferably, the master batch method is used.

Specifically, in the master batch method, when a butyl-rubber-based adhesive composition is prepared, for example, a part of the tackifier and the softener are formulated as final batch components while, as master batch components, the other individual components (the butyl rubber, the filler, and the remainder of the tackifier) are formulated. The master batch components are kneaded first to prepare a master batch, and then the obtained master batch and the final batch components are kneaded to obtain a kneaded product.

Then, from the adhesive composition (kneaded product) thus obtained, the rubber-based adhesive layer 2 is formed.

To form the rubber-based adhesive layer from the rubber-based adhesive composition, the adhesive composition described above is molded into a sheet shape by a molding method such as, e.g., mixing roll molding, calendar roll molding, extrusion molding, or press molding.

Thereafter, as necessary, a released sheet (not shown) is laminated on each of the top surface and back surface of the obtained rubber-based adhesive layer 2.

As shown in FIG. 2, in the adhesive seal material for an end portion of a solar cell panel of the present invention, the rubber-based adhesive layer 2 may also be laminated on each of the both surfaces of the base material 4. However, it is also possible that the rubber-based adhesive layers 2 may be directly laminated on each other without using the base material 4, or the rubber-based adhesive layer 2′ made of a rubber-based adhesive composition different from that of the rubber-based adhesive layer 2 may also be laminated. Otherwise, a single layer including only the rubber-based adhesive layer 2 may also be provided.

The thickness of the rubber-based adhesive layer 2 thus formed is in a range of, e.g., 100 to 1000 μm, or preferably 150 to 900 μm. When the thickness is within the range shown above, the non-adhesive layer can be embedded in the rubber-based adhesive layer 2 by compression.

The total thickness of the rubber-based adhesive layer 2 and the base material 4 is in a range of, e.g., 200 to 1200 μm, or preferably 300 to 1000 μm. When the thickness is within the range shown above, the non-adhesive layer can be embedded in the rubber-based adhesive layer 2 by compression.

### (Non-Adhesive Layer)

In the present invention, the non-adhesive layer 3 is formed on the adhesive surface (top surface) of the rubber-based adhesive layer 2 to partially cover the adhesive surface (top surface) of the rubber-based adhesive layer 2. Accordingly, on the surface of the rubber-based adhesive layer 2 where the non-adhesive layer 3 is formed, the contact between the rubber-based adhesive layer 2 and an adherend is controlled, and both of adhesiveness in a thickness direction (the thickness direction of the adhesive layer) and lubricity in a horizontal direction (a surface direction of adhesive seal material 1, a direction along with the surface of adhesive seal material 1, or direction perpendicular to the thickness direction of the adhesive layer 2) can be obtained.

That is, in the adhesive seal material 1 for an end portion of a solar cell panel of the present invention, the non-adhesive layer 3 is provided so as to cover the surface of the rubber-based adhesive layer 2. Therefore, when the adhesive seal material 1 comes in contact with the adherend under no applied pressure, the non-adhesive layer 3 comes in contact with the adherend, while the rubber-based adhesive layer 2 is less likely to come in contact with the adherend. Since the non-adhesive layer 3 does not exhibit an adhesive force, excellent lubricity (slide) can be obtained in the horizontal direction. On the other hand, by press-bonding (bonding under applied pressure) the adhesive seal material 1 of the present invention to the adherend, the non-adhesive layer 3 is pressed into the adhesive layer 2 so that the adhesive layer 2 comes in contact with the adherend. This allows the adhesive seal material 1 to exhibit an adhesive force, and reliably adhere to and seal the adherend.

In the adhesive seal material for an end portion of a solar cell panel of the present invention, the material of the non-adhesive layer 3 is not particularly limited as long as the material does not exhibit an adhesive force at a room temperature. Examples of such a material to be used include a thermosetting resin such as an epoxy resin, a polyimide resin, a phenol resin, a urea resin, a melamine resin, an unsaturated polyester resin, a diallyl phthalate resin, a silicone resin, or a urethane resin, a thermoplastic resin such as polyethylene, polypropylene, polyester, or nylon, an inorganic material such as glass beads, glass balloon, glass fiber, silica beads, aluminum oxide, or silica, and the like. The materials shown above may have irregular shapes as resin compositions, fibrous or rod-like shapes, or bead-like or balloon-like shapes.

The configuration of the non-adhesive layer 3 is not particularly limited as long as the non-adhesive layer 3 has a configuration that can partially cover the surface of the adhesive layer 2. The non-adhesive layer 3 may be formed in a dotted (punctuate) configuration, a linear configuration in which lines are spaced apart at given intervals, or a net-like or mesh-like configuration. When the non-adhesive layer 3 is made of a fibrous material, the non-adhesive layer 3 may also be formed in a vertical direction from the surface of the rubber-based adhesive layer 2.

A forming method of the non-adhesive layer 3 is not particularly limited. Depending on the properties of a material to be used or on a configuration into which the non-adhesive layer 3 is formed, an appropriate method can be selected appropriately. For example, when the non-adhesive layer 3 is made of the thermosetting resin or thermoplastic resin shown above, the non-adhesive layer 3 can be formed by gravure coating or dot coating. When the non-adhesive layer 3 is formed into a net-like configuration, the non-adhesive layer 3 can be formed by forming a net or the like in advance, and bonding the net or the like to the rubber-based adhesive layer with the adhesive force of the rubber-based adhesive layer.

The thickness of the non-adhesive layer 3 is preferably in a range of, e.g., 10 to 1000 μm, or more preferably 50 to 900 μm. When the thickness is less than 10 μm, lubricity may be poor. On the other hand, when the thickness exceeds 1000 μm, it may be impossible to obtain both of the adhesiveness and the lubricity.

A ratio in which the non-adhesive layer 3 covers the rubber-based adhesive layer 2, or the coverage ratio (the ratio of the projection area of the non-adhesive layer 3 to the area of the rubber-based adhesive layer 2) is not particularly limited, and may be adjusted appropriately within a range of, e.g., 5% to 95%. The coverage ratio is preferably in the range of 5% to 50%, or more preferably 10% to 40%. When the coverage ratio is less than 5%, the lubricity may be poor. On the other hand, when the coverage ratio exceeds 50%, it may be impossible to obtain both of the adhesiveness and the lubricity.

Note that the coverage ratio of the non-adhesive layer 3 can be calculated from the weight ratio between sample sheets, which is obtained by producing an enlarged duplication (under, e.g., 16-fold magnification) of a surface (measuring, e.g., 20 mm×20 mm) covered with the non-adhesive layer 3, cutting the obtained duplication into an adhesive-layer part and a non-adhesive-layer part with scissors, and measuring the weight of each of the cut sample sheets. Otherwise, the coverage ratio can be calculated by performing image analysis of a photograph of the surface of the rubber-based adhesive layer 2 covered with the non-adhesive layer 3. When a porous screen is used as the non-adhesive layer 3, the coverage ratio can also be calculated by subtracting the aperture ratio thereof from 100.

As the non-adhesive layer 3 in the adhesive seal material for an end portion of a solar cell panel of the present invention, a porous screen is preferably used in terms of improving both of the lubricity and tackiness.

### (Porous Screen)

A porous screen is a screen with pores, i.e., a multi-pore (or perforated) sheet-like material. Note that, in the present invention, a porous screen also includes a net-like material.

Specific examples of such a porous screen to be used are not particularly limited, and include a net (a net-like material such as a plastic net, a fiber net, or a metallic yarn net), a woven fabric, a non-woven fabric, a paper sheet, and the like. Alternatively, for example, a plastic sheet, a thin metal sheet, a woven fabric, a non-woven fabric, a paper sheet, or the like which is perforated (which may be referred to also as “sheet having pores” may also be used. Among them, a net or a sheet having pores is preferred, and a net is particularly preferred.

The shapes of the pores or meshes of the porous screen are not particularly limited as long as the properties described above can be obtained, and examples of the shapes to be used include a triangle, a quadrilateral (such as e.g., a square, a rectangle, a rhomboid, or a trapezoid), a circle (such as, e.g., a true circle, a circle approximate to a true circle, or an ellipsoid), and the like. Alternatively, the shapes may also be irregular shapes similar to the shapes shown above. Note that the shapes of the pores or meshes may be entirely the same or different from each other.

The thickness of the porous screen is not particularly limited as long as the properties described above are obtained, but preferably in a range of, e.g., 10 to 1000 μm, or more preferably 50 to 900 μm. When the thickness is less than 10 μm, the lubricity may be poor. On the other hand, when the thickness exceeds 1000 μm, it may be impossible to obtain both of the adhesiveness and the lubricity.

When the porous screen is a net, the raw material thereof is not particularly limited, and examples of the raw material thereof include a synthetic resin (plastic) such as nylon, polyethylene, polypropylene, or polyester, a natural fiber, a metal fiber, and the like.

The basis weight of the porous screen is not particularly limited but, in terms of improving both of the adhesiveness and lubricity of the adhesive surface to which the porous screen is bonded, the basis weight is preferably in a range of, e.g., 10 to 200 g/m², or more preferably 20 to 160 g/m². When the basis weight is less than 10 g/m², it leads to a reduction in the strength of the porous screen upon insertion of the frame, and a fracture is likely to be formed. In addition, under no applied pressure, tackiness tends to increase, and insertability into the frame may be poor. On the other hand, when the basis weight exceeds 200 g/m², the high strength of the porous screen increases the repulsion strength when the screen is folded back at a corner portion, which may degrade the adhesiveness.

The sizes of the meshes are not particularly limited but, in terms of improving both of the adhesiveness and the lubricity of the adhesive surface to which the porous screen is bonded, the sizes of the meshes are preferably in a range of 5 meshes/inch to 50 meshes/inch, or more preferably 10 meshes/inch to 40 meshes/inch.

Examples of a commercially available product of such a net include “Net ND 20™” (produced by Daisen Co, Ltd.), and the like.

When the porous sheet is a sheet having pores, the raw material therefor is not particularly limited but, in terms of improving both of the adhesiveness and the lubricity of the adhesive surface to which the porous screen is bonded, a plastic or a non-woven fabric is preferred.

The sizes of the pores of the porous screen are not particularly limited as long as the properties described above can be obtained, and the sizes of the pores may be the same or different from each other. The sizes of the pores in, e.g., the largest pore portion are in a range of about 500 μm to 10 mm.

The distribution of the pores in the screen is not particularly limited as long as the properties described above can be obtained. The pores may be concentrated in a given region, or may be dispersed in the entire porous screen.

The distance between the pores of the porous screen is not particularly limited, and may be or may not be uniform.

### (Other Layers)

The adhesive seal material for an end portion of a solar panel of the present invention may also have other layers (such as, e.g., an intermediate layer or an undercoat layer) as long as the effects of the present invention are not impaired thereby.

### (Base Material)

When the adhesive seal material for an end portion of a solar cell panel of the present invention is of a base-equipped type, the base material 4 is not particularly limited. Examples of the base material 4 to be used include appropriate thin-film materials including a paper base material such as a paper sheet; a fiber base material such as a woven fabric, a non-woven fabric, or a net (the raw material of which is not particularly limited, and can be selected appropriately from, e.g., cotton, spun rayon, manila hemp, rayon, polyester, a pulp fiber, and the like); a metal base material such as a metal foil or a metal plate; a plastic base material such as a plastic film or sheet; a rubber base material such as a rubber sheet; a foam such as an acrylic foam or a foam sheet; and a laminate thereof (such as a laminate of a plastic base material and another base material or a laminate of plastic films (or sheets)), and the like. As the base material, a plastic base material such as a plastic film or sheet can be used appropriately. Examples of the raw material of such a plastic film or sheet include an olefinic resin containing an α-olefin as the monomer component such as polyethylene (PE), polypropylene (PP), an ethylene-propylene copolymer, or an ethylene-vinyl acetate copolymer (EVA); a polyester resin such as polyethylene terephthalate (PET), polyethylene naphthalate (PEN), or polybutylene terephthalate (PBT); polyvinyl chloride (PVC); a vinyl acetate resin; polyphenylene sulfide (PPS); an amide resin such as polyamide (nylon) or wholly aromatic polyamide (aramide); a polyimide resin; polyether ether ketone (PEEK), and the like. These raw materials can be used alone or in a combination of two or more.

When a plastic base material is used as the base material 4, deformability such as the elongation percentage thereof may be controlled by stretching treatment or the like. When the adhesive layer is formed by curing through active-energy ray irradiation, a base material that does not inhibit transmission of the active-energy ray is preferably used as the base material.

To improve the adhesion to the adhesive layer, the surface of the base material 4 may also be subjected to conventional surface treatment, e.g., oxidation treatment according to a chemical or physical method such as corona treatment, chromic acid treatment, ozone exposure, flame exposure, high-voltage electric shock exposure, or ionizing radiation treatment. The surface of the base material 4 may also be subjected to coating treatment or the like with an undercoat agent, an exfoliator, or the like.

The thickness of the base material 4 can be selected appropriately depending on the desired strength, flexibility, intended application, etc. thereof, and is typically in a range of not more than 100 μm (e.g., 1 to 100 μm), or preferably about 10 to 80 μm, but is not limited thereto. The base material may be in any shape, single-layered or laminated.

### (Released Liner)

The adhesive surface (top surface of the adhesive layer) of the adhesive seal material for an end portion of a solar cell panel of the present invention may also be protected (not shown) by a released liner (separator or released film) until being used. Note that the respective adhesive surfaces of the adhesive layers provided on the both surfaces of the adhesive seal material may be protected individually by two released liners or by one released liner having released surfaces on the both sides thereof, and wound in a rolled shape. The released liner is used as a protective material for the adhesive layer, and removed when the adhesive seal material is bonded to the adherend.

Such a released liner is not particularly limited, and any conventional released paper or the like may be used. Examples of such a released liner to be used include a base material having a release-treated layer, a low-adhesive base material made of a fluorine-based polymer, a low-adhesive base material made of a non-polar polymer, and the like. Examples of the low-adhesive base material made of the fluorine-based polymer include a plastic film, a paper sheet, and the like that are surface-treated with an exfoliation treatment agent such as a silicone-based, long-chain alkyl-based, or a fluorine-based agent or molybdenum sulfide. Examples of the fluorine-based polymer of the low-adhesive base material made of the fluorine-based polymer include polytetrafluoroethylene, polychlorotrifluoroethylene, polyvinyl fluoride, polyvinylidene fluoride, a tetrafluoroethylene-hexafluoropropylene copolymer, a chlorofluoroethylene-vinylidene fluoride copolymer, and the like. Examples of the non-polar polymer of the low-adhesive base material made of the non-polar polymer include an olefinic resin (such as, e.g., polyethylene or polypropylene), and the like. Note that the released liner can be formed by a known or conventional method. In addition, the thickness and the like of the released liner are also not particularly limited.

### (Adhesive Seal Material for End Portion of Solar Cell Panel)

A producing method of the adhesive seal material for an end portion of a solar cell panel of the present invention is not particularly limited, and the adhesive seal material can be produced by, e.g., obtaining the rubber-based adhesive layer 2 or the rubber-based adhesive layer 2 having the base material 4 by the method described above, and then bonding the non-adhesive layer 3 to the surface thereof.

More specifically, the no-base-type adhesive seal material for an end portion of a solar cell panel including only the non-adhesive layer 3 and the rubber-based adhesive layer 2 can be produced by, e.g., producing the rubber-based adhesive layer 2 by a known/conventional method, and then providing the non-adhesive layer 3 on the surface of the rubber-based adhesive layer 2.

On the other hand, the base-equipped-type adhesive seal material for an end portion of a solar cell panel including the rubber-based adhesive layer 2 having the surface where the non-adhesive layer 3 is formed and formed on the surface of the base material 4, the rubber-based adhesive layer 2 having the back surface where the non-adhesive layer 3 is not formed and formed on the back surface of the base material 4, and the base material 4 can be produced by obtaining the rubber-based adhesive layer 2 on one surface (top surface) of the base material 4 by a known/conventional method, bonding the non-adhesive layer 3 to the surface of the rubber-based adhesive layer 2 to provide the rubber-based adhesive layer 2 having the non-adhesive layer 3, and further providing the rubber-based adhesive layer 2 having the back surface where the non-adhesive layer 3 is not formed on the other surface (back surface) of the base material 4 by a known/conventional method.

Alternatively, the base-equipped-type adhesive seal material can also be produced by providing the rubber-based adhesive layer 2 on each of the both surfaces of the base material 4 by a known/conventional method, and then bonding the non-adhesive layer 3 to one surface (top surface) of the rubber-based adhesive layer 2.

In the lamination of the rubber-based adhesive layer 2 to the base material 4, the rubber-based adhesive layer 2 can be pressure-bonded to the base material 4 under a pressure in a range of, e.g., 0.1 to 1.0 MPa, or preferably 0.2 to 0.5 MPa.

Examples of conditions for pressure-bonding when a fibrous material such as a porous screen or a granular material is bonded as the non-adhesive material 3 to the rubber-based adhesive layer 2 include a pressure in a range of, e.g., 0.1 to 1.0 MPa, or particularly 0.2 to 0.5 MPa. When the pressure applied upon bonding together is excessively high, the non-adhesive layer 3 is embedded in the rubber-based adhesive layer 2, and the effect achieved by including the non-adhesive layer 3 is not achieved. Accordingly, it is desirable to adjust the conditions for pressure-bonding such that about half of the non-adhesive layer 3 is embedded in the rubber-based adhesive layer 2.

It is desirable that, to each of the top surface of the rubber-based adhesive layer 2 to which the non-adhesive layer 3 is bonded and the back surface of the rubber-based adhesive layer 2 to which the non-adhesive layer 3 is not bonded, a released liner (separator or released film) is bonded for the protection thereof till the adhesive seal material is used.

Thereafter, according to the peripheral length and thickness (the length of a solar cell panel in the thickness direction thereof) of the peripheral end surface of the solar cell panel, the adhesive seal material 1 is trimmed (cut) into an elongated flat-belt shape as necessary.

In the present invention, the adhesive surface (top surface) of the rubber-based adhesive layer 2 covered with the non-adhesive layer 3 has both of adhesiveness and lubricity. More specifically, the adhesive surface exhibits adhesiveness in the thickness direction of the rubber-based adhesive layer 2 on which the none-adhesive layer 3 is formed, while exhibiting lubricity in the surface direction (the direction along with adhesive seal material 1, or the direction perpendicular to the thickness direction mentioned above, or the horizontal direction) of the rubber-based adhesive layer 2 on which the non-adhesive layer 3 is formed. The properties of adhesiveness and lubricity are described hereinbelow with reference to FIG. 3.

In FIG. 3, 2 denotes the rubber-based adhesive layer, 3 denotes the non-adhesive layer, and 5 denotes an object in contact therewith.

FIG. 3 shows the rubber-based adhesive layer 2 having one adhesive surface (top surface) where the non-adhesive layer 3 is formed, and an object in contact with the surface thereof where the non-adhesive layer 3 is formed, (a) showing a schematic cross-sectional view thereof in a state without applied pressure, and (b) is a schematic cross-sectional view thereof in a state with applied pressure. In FIG. 3, the base material 4 and the rubber-based adhesive layer 2 on which the non-adhesive layer 3 is not provided are omitted for clear understanding of the property of adhesiveness.

The adhesive surface (top surface) of the rubber-based adhesive layer 2 covered with the non-adhesive layer 3 exhibits such properties as described above because, in the state without applied pressure, the non-adhesive layer 3 is partly embedded in the rubber-based adhesive layer 2 (see FIG. 2 in which about half of the non-adhesively layer 3 is buried), i.e., the non-adhesive layer 3 upwardly protrudes from the top surface of the rubber-based adhesive layer 2, and therefore the top surface of the rubber-based adhesive layer 2 is inhibited from coming into contact with the object 5 (see FIG. 3(a)) while, in the state with applied pressure (state where the top surface of the adhesive layer 2 is in contact with the object 5 under sufficient contact pressure), the non-adhesive layer 3 is pressed into the rubber-based adhesive layer 2 to deform the rubber-based adhesive layer 2, which in turn compressively deforms the non-adhesive layer 3, and upwardly protrudes through the meshes of the non-adhesive layer 3 to come in contact with the object 5 (see FIG. 3(b)).

Note that the degree to which the non-adhesive layer 3 is embedded in each of the state without applied pressure and the state with applied state is not particularly limited as long as the properties described above are obtained.

As a condition for pressure-bonding (pressure for bonding together) when the rubber-based adhesive layer 2 covered with the non-adhesive layer 3 is bonded to the object in contact therewith, a pressure under which the non-adhesive layer 3 is at least buried into the rubber-based adhesive layer needs to be applied, which is in a range of, e.g., 1.0 to 8.0 MPa, or preferably 1.5 to 6.0 MPa. When the pressure upon bonding together is excessively low, a sufficient adhesive force may not be able to be obtained. On the other hand, when the pressure is excessively high, a problem arises that the adhesive layer not only extends out over the surface of the solar cell, but also destroys the base materials 4 and the non-adhesive layer 3.

The adhesive seal material for an end portion of a solar cell panel of the present invention is trimmed into a size of 2 cm×2 cm to produce a sample. The surface of the rubber-based adhesive layer 2 of the sample where the non-adhesive layer 3 is formed is brought into contact with an aluminum plate (produced under the tradename of “SK-A Aluminum Plate 1050P” by SUMITOMO LIGHT METAL INDUSTRIES, Ltd) while a load of 30 g is placed on the sample, and the sample described above is pulled in a surface direction (a horizontal direction) at a speed of 300 mm/minute. A frictional force defined as a stress during the pulling is in a range of 0.01 to 1.0 N/4 cm², or preferably 0.01 to 0.5 N/4 cm². When the frictional force exceeds 1.0 N/4 cm², a problem may occur in terms of lubricity.

In the present invention, a shear adhesive force (with respect to the aluminum plate at a pulling rate of 300 mm/minute) at the adhesive surface of the rubber-based adhesive layer 2 covered with the non-adhesive layer 3 is not particularly limited, but is in a range of not less than 5 N/4 cm², preferably not less than 20 N/4 cm², or more preferably not less than 40 N/4 cm² (normally not more than 200 N/4 cm²) in terms of improving both of the adhesiveness and the lubricity. When the sheer adhesive force is less than 5 N/4 cm², the seal material is not solidly fixed in the frame, and sealability may decrease.

That is, an aspect of the present invention is the adhesive seal material 1 for an end portion of a solar cell panel having the rubber-based adhesive layer 2. The adhesive seal material 1 is trimmed into a size of 2 cm×2 cm to produce a sample, the surface of the rubber-based adhesive layer 2 of the sample where the non-adhesive layer 3 is formed is brought into contact with an aluminum plate while a load of 30 g is placed on the sample, and the sample is pulled in a horizontal direction at a speed of 300 mm/minute. A frictional force defined as a stress during the pulling is in a range of 0.01 to 1.0 N/4 cm², and a shear adhesive force (with respect to the aluminum plate at a pulling rate of 300 mm/minute) is not less than 5 N/4 cm². Therefore, the adhesive surface of the adhesive seal material 1 has both of the lubricity and the adhesiveness.

In the present invention, the adhesive seal material 1 has a moisture permeability at a temperature of 40° C. and a relative humidity of 90% in accordance with a moisture permeability test method of JIS Z0208 which is in a range of, e.g., 0.1 to 10 g/m²/24 hours, preferably 0.2 to 5 g/m²/24 hours, or more preferably 0.4 to 2 g/m²/24 hours. When the moisture permeability described above exceeds 10 g/m²/24 hours, an excellent water vapor barrier property may not be able to be obtained.

### (Solar Cell Module)

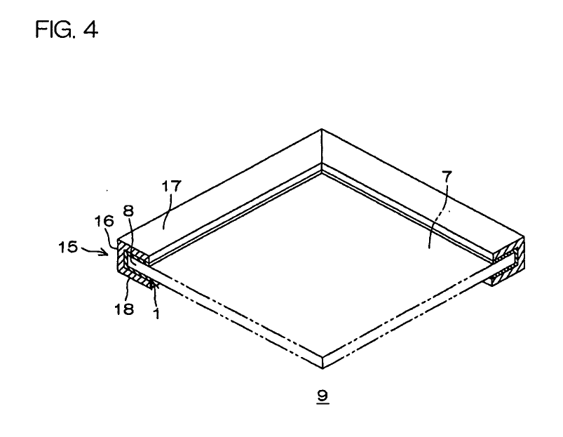

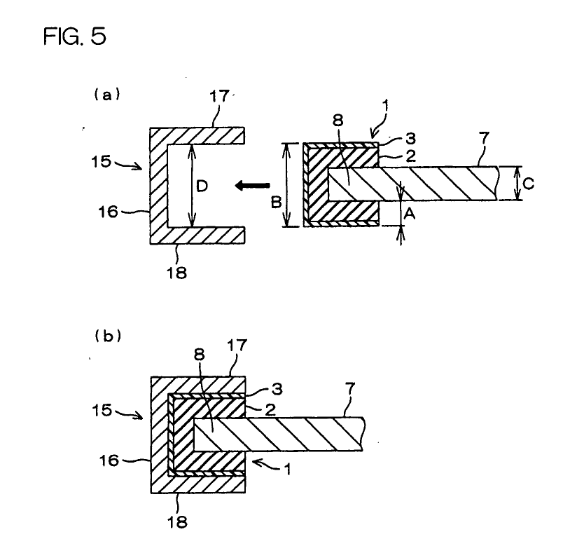

Next, a solar cell module 9 using the adhesive seal material 1 is described with reference to FIGS. 4 and 5. In FIGS. 4 and 5, the solar cell module 9 includes a solar cell panel 7, the adhesive seal material 1, and a frame 15 as a fixing member.

The solar cell panel 7 has a generally rectangular flat plate shape, and a thickness C thereof is in a range of, e.g., 2 to 10 mm, or preferably 4 to 6 mm.

As described above, the adhesive seal material 1 is formed in a sheet-like or film-like shape extending in the longitudinal direction, and seals a peripheral end portion 8 of the solar cell panel 7.

More specifically, as shown in FIG. 5(a), the adhesive seal material 1 is disposed in a generally U-shaped cross-sectional shape in contact with the side surface, top surface (upper surface), and back surface (lower surface) of the peripheral end portion 8 of the solar cell panel 7. Specifically, the adhesive surface of the adhesive seal material 1 where the non-adhesive layer 3 is not provided is bonded to the peripheral end portion 8 of the solar cell panel 7 so as to come in contact with each of the foregoing surfaces of the peripheral end portion 8 of the solar cell panel 7.

The frame 15 is provided along each of the sides of the solar cell panel 7. The frame 15 is formed in a generally U-shaped cross-sectional shape which is inwardly opened, and integrally includes a side wall 16 in a flat-plate shape, a top wall 17 in a flat-plate shape extending inwardly from an upper portion of the side wall 16, and a back wall 18 in a flat-plate shape extending inwardly from a lower portion of the side wall 16. The distance D between the top wall 17 and the back wall 18 is substantially the same as or slightly smaller than a total thickness B of the thickness C of the solar cell panel 7 and a thickness 2A (2×A) of the adhesive seal material 1 laminated on the top surface and back surface thereof. Specifically, the distance D is in a range of, e.g., 80% to 100%, or preferably 90% to 100% of the total thickness B described above. Specifically, the distance D between the top wall 17 and the back wall 18 is in a range of 3000 to 10000 μm, or preferably 4000 to 8000 μm.

The frame 15 is formed of, e.g., a metal material (such as aluminum) or a resin material, and preferably formed of aluminum. The frame 15 has longitudinal end portions along the individual sides thereof which are joined to each other to form four corners, and assembled in a frame shape when viewed in plan view.

The frame 15 sandwiches the adhesive seal material 1 bonded to the peripheral end portion 8 of the solar cell panel 7. Specifically, the adhesive seal material 1 is bonded such that the surface of the adhesive layer thereof where the non-adhesive layer is provided is in contact with the frame 15, the top wall 17 covers the adhesive seal material 1 bonded to the top surface of the peripheral end portion 8, the side wall 16 covers the adhesive seal material 1 bonded to the side surface of the peripheral end portion 8, and the back surface 18 covers the adhesive seal material 1 bonded to the back surface of the peripheral end portion 8.

Next, a producing method of the solar cell module 9 is described with reference to FIGS. 4 and 5.

First, in the method, the adhesive seal material 1 is bonded to the peripheral end portion 8 of the solar cell pane 7, as shown in FIG. 5(a).

To bond the adhesive seal material 1 to the solar cell panel 7, the adhesive surface of the rubber-based adhesive layer 2 of the adhesive seal material 1 where the non-adhesive layer 3 is not provided is brought into contact with each of the surfaces of the peripheral end portion 8 such that the foregoing configuration is obtained.

Next, as shown by the arrow of FIG. 5(a) and in FIG. 5(b), the peripheral end portion 8 of the solar cell panel 7 to which the adhesive seal material 1 is bonded is disposed in the frame 15.

More specifically, the peripheral end portion 8 of the solar cell panel 7 to which the adhesive seal material 1 is bonded is inserted into the space between the top wall 17 and the back wall 18 such that the side surface thereof comes in contact with the side wall 16, and the surface of the adhesive layer where the non-adhesive layer 3 is provided is bonded to the frame 15 in contact relation therewith.

In the insertion of the peripheral end portion 8 into the frame 15, it is preferable that the adhesive seal material 1 laminated on the surface of the peripheral end portion 8 comes in contact with the top wall 17 with no gap formed therebetween, and the adhesive seal material 1 laminated on the back surface of the peripheral end portion 8 comes in contact with the ball wall 18 with no gap formed therebetween.

Next, the solar cell panel 7 and the frame 15 are brought into a state with applied pressure so that the non-adhesive layer 3 provided on the surface of the rubber-based adhesive layer 2 is pressed into the adhesive layer, and the rubber-based adhesive layer 2 protruding through the meshes comes in contact with the side wall 16, top wall 17, and back wall 18 of the frame 15 to increase the adhesive force.

This brings the adhesive seal material 1 into close adhesion to the frame 15, and the movement of the peripheral end portion 8 of the solar cell panel 7 in the thickness direction and the direction of insertion (perpendicular to the thickness direction) is restricted by the adhesive seal material 1 and the frame 15. As a result, the peripheral end portion 8 of the solar cell panel 7 is fixed in the frame 15.

That is, the peripheral end portion 8 of the solar cell panel 7 is sealed with the adhesive seal material 1.

In this manner, the solar cell module 9 can be assembled. That is, a sealed structure of the peripheral end portion 8 of the solar cell panel 7 is formed in which the peripheral end portion 8 of the solar cell panel 7 is fixed with the frame 15 via the adhesive seal material 1. More specifically, a sealed structure of the peripheral end portion 8 of the solar cell panel 7 is formed in which the surface of the adhesive layer of the adhesive seal material 1 where the non-adhesive layer is provided is bonded to the frame 15 in contact relation therewith, and fixed.

The adhesive seal material 1 easily adheres to the peripheral end portion 8 of the solar cell panel 7, and the peripheral end portion 8 of the solar cell panel 7 with the adhesive seal material 1 can be disposed in the frame 15 with high workability.

Thereafter, by applying a proper pressure, the adhesive force of the adhesive seal material 1 is increased. Therefore, it is possible to securely fix the peripheral end portion 8 of the solar cell panel 7 with the frame 15 via the adhesive seal material 1, and reliably seal the peripheral end portion 8 of the solar cell panel 7. This allows the peripheral end portion 8 of the solar cell panel 7 to have an excellent water vapor barrier property.

In addition, the adhesive force of the adhesive seal material 1 bonded to the peripheral end portion 8 of the solar cell panel 7 can be increased by applying a proper pressure without performing heating. As a result, the solar cell module 9 can be efficiently produced.

Moreover, immediately after the adhesive seal material 1 is bonded to the peripheral end portion 8 of the solar cell panel 7, the adhesive force thereof has been controlled to be relatively low.

Accordingly, after the peripheral end portion 8 of the solar cell panel 7 to which the adhesive seal material 1 is bonded is inserted into the frame 15, the peripheral end portion 8 thereof can be temporarily removed therefrom, and then easily inserted therein again (rework).

Therefore, it is possible to precisely dispose the peripheral end portion 8 of the solar cell panel 7 to which the adhesive seal material 1 is bonded in the frame 15, and then more reliably seal the peripheral end portion 8 of the solar cell panel 7.

On the other hand, if the adhesive force of the adhesive seal material 1 is higher than initially, a modification treatment step of applying a surface tension modifier such as soap water or the like is required to reduce the adhesive force with respect to the frame 15.

However, since the adhesive force of the adhesive seal material 1 has been controlled to be lower than initially, the peripheral end portion 8 of the solar cell panel 7 to which the adhesive seal material 1 is bonded can be inserted into the frame 15 with higher workability.

The modification treatment step described above may leave moisture in the solar cell module 9.

However, in accordance with the method described above, the peripheral end portion 8 of the solar cell panel 7 to which the adhesive seal material 1 is bonded can be inserted into the frame 15 with high workability without performing the modification treatment step described above.

As a result, it is possible to obtain the solar cell module 9 having excellent water resistance and reliability, while ensuring high workability and high production efficiency.

### EXAMPLES

Hereinbelow, the present invention is described more specifically based on the examples thereof. However, the present invention is by no means limited the examples.

### (Porous Screen A)

As a porous screen A, a mesh screen made of polyester, having a thickness of 0.50 mm, a basis weight of 70 g/m², a mesh size of 2.0 mm×1.5 mm, and a coverage ratio of 14% was used.

### (Porous Screen B)

As a porous screen B, a mesh screen made of nylon, having a thickness of 0.35 mm, a basis weight of 40 g/m², a mesh size of 1.5 mm×1.5 mm, and a coverage ratio of 11% was used.

### (Porous Screen C)

As a porous screen C, a mesh screen made of polyethylene, having a thickness of 0.80 mm, a basis weight of 140 g/m², a mesh size of 1.0 mm×1.0 mm, and a coverage ratio of 18% was used.

### (Preparation of Rubber-Based Adhesive Composition 1)

Using a 190 L Banbury mixer, 70 parts by weight of a reclaimed butyl rubber (having a Mooney viscosity of 44±6 (ML1+4, 100° C.), 30 parts by weight of a butyl rubber (produced under the tradename of “JSR BUTYL 268” by JSR Corporation), 100 parts by weight of heavy calcium carbonate, 0.1 parts by weight of light calcium carbonate, and 10 parts by weight of polybutene (liquid polybutene produced under the tradename of “HV-300” by Nippon Petrochemicals Co., Ltd.) were kneaded at a temperature of 120° C. to prepare a master batch.

Then, the above master batch was charged into a 75 L pressure kneader, and then 40 parts by weight of a tackifier (petroleum-based resin produced under the tradename of “Escorez 1202U” by TONEX Co., Ltd.), 50 parts by weight of polybutene (liquid polybutene produced under the tradename of “HV-300” by Nippon Petrochemicals Co., Ltd.), and 5 parts by weight of a process oil (produced under the tradename of “Cumic Process Oil 8465” by Shin Nihon Yushi Kogyo Co., Ltd.) were added to the kneader, after that they were kneaded at a temperature of 120° C. and under an applied pressure in the range of 0.1 to 0.3 MPa to prepare a rubber-based adhesive composition 1.

### (Formation of Rubber-Based Adhesive Layer 1)

The rubber-based adhesive composition 1 was calendared with a calendar roll to form a rubber-based adhesive layer 1 having a thickness of 200 μm, and laminated on each of the top surface and back surface of a PET film having a thickness of 25 μm. Thereafter, a released sheet was laminated on each of the both surfaces (the top surface of a first adhesive layer and the back surface of a second adhesive layer) of the obtained rubber-based adhesive layer.

### (Preparation of Rubber-Based Adhesive Composition 2)

Using a 75 L pressure kneader, 100 parts by weight of a reclaimed butyl rubber (having a Mooney viscosity of 44±6 (ML1+4, 100° C.), 200 parts by weight of heavy calcium carbonate, 100 parts by weight of polybutene (liquid polybutene produced under the tradename of “HV-300” by Nippon Petrochemicals Co., Ltd.), and a cross-linking agent (produced under the tradename of “Vulnoc DNB” by Ouchi-Shinko Chemical Industrial Co., Ltd.) were kneaded at a temperature of 120° C. to prepare a rubber-based adhesive composition 2.

### (Formation of Rubber-Based Adhesive Layer 2)

The rubber-based adhesive composition 2 was calendared with a calendar roll to form a rubber-based adhesive layer 2 having a thickness of 200 μm, and laminated on each of the top surface and back surface of a PET film having a thickness of 25 μm. Thereafter, a released sheet was laminated on each of the both surfaces (the top surface of a first adhesive layer and the back surface of a second adhesive layer) of the obtained rubber-based adhesive layer.

### Example 1

The released sheet laminated on the top surface of the first adhesive layer of the rubber-based adhesive layer 1 obtained by the foregoing process was peeled therefrom and, using a quadriaxial laminator, the porous screen A was bonded as a non-adhesive layer to the top surface of the first adhesive layer under a pressure of 0.2 MPa such that the meshes of the net had uniform shapes to provide an adhesive seal material for an end portion of a solar cell panel which had a rubber-based adhesive layer having one adhesive surface covered with the porous screen.

### Examples 2 to 6

Using the rubber-based adhesive layers 1 and 2 shown above each as a rubber-based adhesive layer and using the porous screens A to C shown above each as a porous screen, adhesive seal materials each for an end portion of a solar cell panel were obtained in the combinations shown in Table 1 in the same manner as in Example 1.

### Comparative Examples 1 and 2

Rubber-based adhesive sheets 1 and 2 (i.e., PET films each having both surfaces thereof on which rubber-based adhesive layers made of the rubber-based adhesive compositions 1 and 2 are provided and to which porous screens are not bonded) were provided as respective adhesive seal materials each for an end portion of a solar cell panel of Comparative Examples 1 and 2.

### Comparative Examples 3 to 5

Bubble-containing acrylic adhesive layers which were each produced according to the following formula and to which the porous screens A to C were bonded as non-adhesive layers were provided respectively as Comparative Examples 3 to 5.

Into a monomer mixture of 90 parts by weight of 2-ethylhexyl acrylate and 10 parts by weight of an acrylic acid as the monomer components, 0.05 parts by weight of a photoinitiator (produced under the tradename of “Irgacure 651” by Nippon Ciba Geigy Co, Ltd.) and 0.05 parts by weight of a photoinitiator (produced under the tradename of “Irgacure 184” by Nippon Ciba Geigy Co, Ltd.) were mixed, and the mixture was irradiated with a UV ray till the viscosity thereof (measured with BH viscometer, rotor: No. 5, revolution: 10 rpm, and measuring temperature: 30 C.°) reached approximately 15 Pa·s to produce a partially polymerized acrylic composition. To 100 parts by weight of the acrylic composition, 0.04 parts by weight of the photoinitiator (produced under the tradename of “Irgacure 651” by Nippon Ciba Geigy Co., Ltd.), 0.1 parts by weight of 1,6-hexanediol diacrylate, 0.7 parts by weight of a surface active agent (produced under the tradename of “Megaface F-477” by DIC Corporation), and 0.02 parts by weight of carbon black were added. In addition, hollow glass balloons (produced under the tradename of “CEL-STAR Z-27” by Tokai Kogyo Co., Ltd.) were added to the acrylic composition at a ratio of 30 capacity % to the entire volume of the acrylic composition to produce an acrylic adhesive precursor. Note that the entire volume of the hollow glass balloons in the acrylic adhesive precursor was about 23 capacity % based on the entire volume of the acrylic adhesive precursor. Nitrogen was introduced into the acrylic adhesive precursor to mix bubbles therein using a device including a disc having a through hole at the center portion thereof, a stator having fine gear teeth, and a rotor having the same fine gear teeth as those of the stator, and located over the disc. Nitrogen was introduced until the amount of the mixed bubbles reached approximately 15 capacity % based on the entire volume of the ejected liquid to provide a bubble-containing acrylic adhesive composition.

The bubble-containing acrylic adhesive composition was guided to a wet-lamination roll coater through a tube (having a diameter of 19 mm and a length of 1.5 m), and coated on respective release-treated one surfaces of two polyethylene terephthalate base materials to be located therebetween such that the foregoing bubble-containing acrylic adhesive composition had a thickness of 1.2 mm after drying and curing. In other words, the bubble-containing acrylic adhesive composition was sandwiched between the polyethylene terephthalate base materials. Then, an ultraviolet ray at an illuminance of 5 mW/cm² was emitted to irradiate the both surfaces for four minutes to cure the bubble-containing acrylic adhesive composition, and produce a bubble-containing acrylic adhesive layer.

A plurality of pieces of the bubble-containing acrylic adhesive layer were prepared and, to respective one adhesive surfaces of the pieces, the porous screens A to C were bonded each under a pressure of 0.2 MPa using a quadriaxial laminator such that the meshes of the nets had uniform shapes to provide adhesive seal materials each for an end portion of a solar cell panel which had the bubble-containing acrylic adhesive layers having respective one adhesive surfaces covered with the nets.

### (Evaluation)

For each of EXAMPLES and COMPARATIVE EXAMPLES, a frictional force, a shear adhesive force, and a moisture permeability were measured.

### (Measurement of Frictional Force)

The adhesive seal materials each for an end portion of a solar cell panel of EXAMPLES and COMPARATIVE EXAMPLES were cut into seal material samples each of 2 cm×2 cm. Each of the seal material samples was allowed to stand still on an adherend in a horizontal direction such that the surface of the rubber-based adhesive layer thereof where the porous screen was formed came in contact with the adherend. As the adherend, an aluminum plate (produced under the tradename of “SK-A Aluminum Plate 1050P” by SUMITOMO LIGHT METAL INDUSTRIES, Ltd.) was used.

Then, a 30 g weight was placed on each of the surface of the rubber-based adhesive layer where the porous screen was not formed to fix a load of 30 g to the seal material sample.

Each of the seal material samples was pulled in a horizontal direction (a direction along the aluminum plate) at a speed of 300 mm/minute, and a stress (N/4 cm²) applied thereon during the pulling was measured.

### (Measurement of Shear Adhesive Stress)

In the adhesive seal materials of EXAMPLES and COMPARATIVE EXAMPLES, the released sheets laminated on the adhesive layers where porous screens were not provided were peeled therefrom and, to the surfaces of the adhesive layers thereof, respective PET films each having a thickness of 25 μm were bonded. Then, the adhesive seal materials were cut into pieces each having a width of 20 mm and a length of 120 mm to produce samples for evaluation.

Thereafter, each of the samples for evaluation was placed on the top surface of an aluminum plate such that only a portion of the porous screen surface thereof equivalent to a length of 20 mm faces the top surface of the aluminum plate. By applying a pressure thereto with a 5 kg weight for five minutes, a longitudinal one end portion of the sample for evaluation was bonded to the longitudinal other end portion of the aluminum plate. That is, the contact area between each of the samples for evaluation and the aluminum plate was 4 cm². For COMPARATIVE EXAMPLES 1 and 2, each of the surfaces of the rubber-based adhesive layers was similarly bonded to an aluminum plate.

Then, each of the samples for evaluation was allowed to stand still at a room temperature (23° C.) for 30 minutes for the stabilization (curing) of the bonded (adhesive) state. Subsequently, the longitudinal other end portion of the sample for evaluation was held, while the longitudinal one end portion of the aluminum plate was held, and the sample for evaluation and the aluminum plate were each pulled (peeled) at a speed of 300 mm/second in a direction apart from each other in the longitudinal direction. In this manner, a shear adhesive force (N/4 cm²) after a lapse of 30 minutes after bonding was measured.

### (Measurement of Moisture Permeability)

For each of the adhesive seal materials of EXAMPLES and COMPARATIVE EXAMPLES, a moisture permeability at a temperature of 40° C. and a relative humidity of 90% according to a moisture permeability test method of JIS Z0208 was measured, and a water vapor barrier property was thereby evaluated.

TABLE 1

| | Rubber- | | | Shear | Moisture |
|---|---|---|---|---|---|
| | Based | | Frictional | Adhesive | Permeability |
| | Adhesive | Porous | Force | Force | [g/m² · |
| | Layer | Screen | [N/4 cm²] | [N/4 cm²] | 24 hours] |
| Example 1 | 1 | A | 0.08 | 130.9 | 0.81 |
| Example 2 | 1 | B | 0.07 | 115.3 | 0.81 |
| Example 3 | 1 | C | 0.07 | 44.3 | 0.81 |
| Example 4 | 2 | A | 0.06 | 77.5 | 0.88 |
| Example 5 | 2 | B | 0.06 | 135.9 | 0.88 |
| Example 6 | 2 | C | 0.05 | 8.3 | 0.88 |
| Comparative | 1 | — | 38.7 | 116.3 | 0.81 |
| Example 1 | | | | | |
| Comparative | 2 | — | 32.4 | 98.5 | 0.88 |
| Example 2 | | | | | |
| Comparative | Acrylic | A | 0.06 | 167.7 | 40.0 |
| Example 3 | | | | | |
| Comparative | Acrylic | B | 0.06 | 112.3 | 40.0 |
| Example 4 | | | | | |
| Comparative | Acrylic | C | 0.06 | 61.3 | 40.0 |
| Example 5 | | | | | |

As can be seen from the result of Table 1, each of the adhesive seal materials of EXAMPLES which include the porous screens as the non-adhesive layers formed on the top surfaces of the rubber-based adhesive layers has a significantly low frictional force and satisfactory lubricity in a horizontal direction, and can exhibit adhesiveness under applied pressure. Therefore, the adhesive seal material can be easily bonded to an end portion of a solar cell panel, and the end portion of the solar cell panel with the adhesive seal material can be disposed in a fixing member with high workability. Through subsequent application of pressure, the adhesive force of the adhesive seal material is increased, and therefore it is possible to securely fix the end portion of the solar cell panel with the fixing member via the adhesive seal material, and reliably seal the end portion of the solar cell panel. Since the rubber-based adhesive layer is used as the seal material, the moisture permeability is low, and the end portion of the solar cell panel is allowed to have an excellent water vapor barrier property.

On the other hand, each of the adhesive seal materials of COMPARATIVE EXAMPLES 1 and 2 which do not include porous screens has a high frictional force and a problem associated with workability in a fixing member. It can also be seen that, in each of COMPARATIVE EXAMPLES 3 to 5 using the bubble-containing acrylic adhesive layers instead of rubber-based adhesive layers, lubricity in a horizontal direction and tackiness can be obtained in the same manner as in EXAMPLES, but the moisture permeability is high, and the water vapor barrier property was poor.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

What is claimed is:

1. An adhesive seal material for an end portion of a solar cell panel which is bonded to an end portion of a solar cell panel, comprising:
a rubber-based adhesive layer; and
a non-adhesive layer partially covering a surface of the rubber-based adhesive layer.

2. The adhesive seal material for the end portion of the solar cell panel according to claim 1, wherein a porous screen is provided as the non-adhesive layer.

3. The adhesive seal material for the end portion of the solar cell panel according to claim 1, wherein the rubber-based adhesive layer is formed from a butyl-rubber-based adhesive composition.

4. The adhesive seal material for the end portion of the solar cell panel according to claim 1, wherein a coverage ratio of the non-adhesive layer is in a range of 5 to 50%.

5. The adhesive seal material for the end portion of the solar cell panel according to claim 1, wherein the adhesive seal material is trimmed into a size of 2 cm×2 cm to produce a sample, the surface of the rubber-based adhesive layer of the sample where the non-adhesive layer is formed is brought into contact with an aluminum plate while a load of 30 g is placed on the sample, the sample is pulled in a direction along the aluminum plate at a speed of 300 mm/minute, and a frictional force defined as a stress during the pulling is in a range of 0.01 to 1.0 N/4 cm².

6. A solar cell module comprising:
a solar cell panel;
an adhesive seal material for an end portion of the solar cell panel which includes a rubber-based adhesive layer and a non-adhesive layer partially covering a surface of the rubber-based adhesive layer, and seals the end portion of the solar cell panel; and
a fixing member for fixing the end portion of the solar cell panel via the adhesive seal material.

7. A sealed structure of an end portion of a solar cell panel, wherein an adhesive seal material for the end portion of the solar cell panel which includes a rubber-based adhesive layer and a non-adhesive layer partially covering a surface of the rubber-based adhesive layer is bonded to the end portion of the solar cell panel, and then the adhesive seal material and the end portion of the solar cell panel are disposed in a fixing member such that the end portion of the solar cell panel is fixed with the fixing member via the adhesive seal material.

8. The sealed structure of the end portion of the solar cell panel according to claim 7, wherein the adhesive seal material is bonded to the end portion of the solar cell panel such that the surface of the rubber-based adhesive layer where the non-adhesive layer is formed comes in contact with the fixing member.

9. A sealing method of an end portion of a solar cell panel, comprising:
bonding an adhesive seal material for the end portion of the solar cell panel which includes a rubber-based adhesive layer and a non-adhesive layer partially covering a surface of the rubber-based adhesive layer to the end portion of the solar cell panel; and
disposing the adhesive seal material and the end portion of the solar cell panel in a fixing member to fix the end portion of the solar cell panel with the fixing member via the adhesive seal material.

10. The sealing method of the end portion of the solar cell panel according to claim 9, wherein the adhesive seal material is bonded to the end portion of the solar cell panel such that the surface of the rubber-based adhesive layer where the non-adhesive layer is formed comes in contact with the fixing member.

11. A producing method of a solar cell module, comprising:
bonding an adhesive seal material for an end portion of a solar cell panel which includes a rubber-based adhesive layer and a non-adhesive layer partially covering a surface of the rubber-based adhesive layer to an end portion of a solar cell panel; and
then disposing the adhesive seal material and the end portion of the solar cell panel in a fixing member to fix the end portion of the solar cell panel with the fixing member via the adhesive seal material.

12. The producing method the solar cell module according to claim 11, wherein the adhesive seal material is bonded to the end portion of the solar cell panel such that the surface of the adhesive layer where the non-adhesive layer is formed comes in contact with the fixing member.
